(19) United States
(12) Patent Application Publication
(10) Pub. No.: US 2020/0051838 A1
(43) Pub. Date: Feb. 13, 2020

(54) METHOD OF MANUFACTURING SEMICONDUCTOR DEVICE

(71) Applicant: KOKUSAI ELECTRIC CORPORATION, Tokyo (JP)

(72) Inventors: Hideharu ITATANI, Toyama-shi (JP); Naofumi OHASHI, Toyama-shi (JP); Tadashi TAKASAKI, Toyama-shi (JP)

(73) Assignee: KOKUSAI ELECTRIC CORPORATION, Tokyo (JP)

(21) Appl. No.: 16/136,536

(22) Filed: Sep. 20, 2018

(30) Foreign Application Priority Data
Aug. 7, 2018 (JP) 2018-148815

(51) Int. Cl. H01L 21/67; C23C 16/455; C23C 16/52; H01J 37/32

(52) U.S. Cl. CPC H01L 21/67248; H01L 21/67253; C23C 16/45565; H01J 37/32449; H01J 37/32926; H01J 37/3288; H01J 37/32834; C23C 16/52

(57) ABSTRACT

There is provided a technique that includes: forming a film by heating a substrate held on a substrate mounting table and supplying gas from a shower head to the substrate; performing a first temperature measurement by measuring a first temperature of the shower head and storing a measurement value of the first temperature as reference data; setting processing of a subsequent substrate; performing a second temperature measurement by measuring a second temperature of the shower head before loading the subsequent substrate; calculating a difference between the first temperature and the second temperature; and adjusting a temperature of the shower head to be equal to the first temperature by operating the heater and adjusting a distance between the shower head and the substrate mounting table according to the difference between the first temperature and the second temperature.

### CROSS-REFERENCE TO RELATED APPLICATION

This application is based upon and claims the benefit of priority from Japanese Patent Application No. 2018-148815, filed on Aug. 7, 2018, the entire contents of which are incorporated herein by reference.

### TECHNICAL FIELD

The present disclosure relates to a method of manufacturing a semiconductor device.

### BACKGROUND

As an apparatus for manufacturing a semiconductor device, there is a single wafer processing apparatus for processing substrates one by one. In the single wafer processing apparatus, for example, a film constituting a part of a semiconductor device is formed by heating the substrates and supplying a gas to the substrates.

In the case of forming the same kind of film on a plurality of substrates, the same temperature condition may be set. The substrate temperature is influenced by a heater or a wall of a process chamber.

When processing a plurality of substrates, it is necessary to replace the substrates. However, when replacing the substrates, the processing environment may change before and after the replacement, for example, the temperature of the process chamber decreases. As a result, the quality of a film may vary between the substrates.

### SUMMARY

The present disclosure provides some embodiments that make a film quality between substrates uniform even when a processing environment between the substrates changes in a substrate processing apparatus that heat-treats substrates.

According to one embodiment of the present disclosure, there is provided a method of manufacturing a semiconductor device that includes: forming a film by heating a substrate held on a substrate mounting table by a heater installed in the substrate mounting table and supplying a gas from a shower head installed at a position facing the substrate mounting table to the substrate; performing a first temperature measurement by measuring a first temperature of the shower head and storing a measurement value of the first temperature as reference data in a storage part; setting processing of a subsequent substrate to be processed subsequently; performing a second temperature measurement by measuring a second temperature of the shower head before loading the subsequent substrate; calculating a difference between the first temperature and the second temperature; and adjusting a temperature of the shower head to be equal to the first temperature by operating the heater and adjusting a distance between the shower head and the substrate mounting table according to the difference between the first temperature and the second temperature, in a state where the substrate is not held on the substrate mounting table.

### BRIEF DESCRIPTION OF DRAWINGS

FIG. 1 is an explanatory view illustrating a schematic configuration example of a substrate processing apparatus according to a first embodiment of the present disclosure.

FIG. 2 is an explanatory diagram illustrating a controller of the substrate processing apparatus according to the first embodiment of the present disclosure.

FIG. 3 is an explanatory diagram illustrating a table of a controller according to the first embodiment of the present disclosure.

FIG. 4 is an explanatory diagram illustrating a table of the controller according to the first embodiment of the present disclosure.

FIG. 5 is an explanatory diagram illustrating a table of the controller according to the first embodiment of the present disclosure.

FIG. 6 is an explanatory view illustrating a position of a substrate mounting table according to the first embodiment of the present disclosure.

FIG. 7 is an explanatory view illustrating a position of the substrate mounting table according to the first embodiment of the present disclosure.

FIG. 8 is an explanatory view illustrating a position of the substrate mounting table according to the first embodiment of the present disclosure.

FIG. 9 is a flowchart illustrating a substrate processing process according to the first embodiment of the present disclosure.

FIG. 10 is a flowchart illustrating a film-forming process according to the first embodiment of the present disclosure.

FIG. 11 is an explanatory diagram illustrating a table of a controller according to a second embodiment of the present disclosure.

FIG. 12 is a flowchart illustrating a substrate processing process according to a third embodiment of the present disclosure.

FIG. 13 is a flowchart illustrating a substrate processing process according to a fourth embodiment of the present disclosure.

FIG. 14 is an explanatory diagram illustrating a table of a controller according to the fourth embodiment of the present disclosure.

FIG. 15 is an explanatory diagram illustrating a position of a substrate mounting table according to the fourth embodiment of the present disclosure.

### DETAILED DESCRIPTION

Embodiments of the present disclosure will now be described in detail with reference to the drawings.

### First Embodiment of the Present Disclosure

First, a first embodiment of the present disclosure will be described.

### (1) Configuration of the Substrate Processing Apparatus

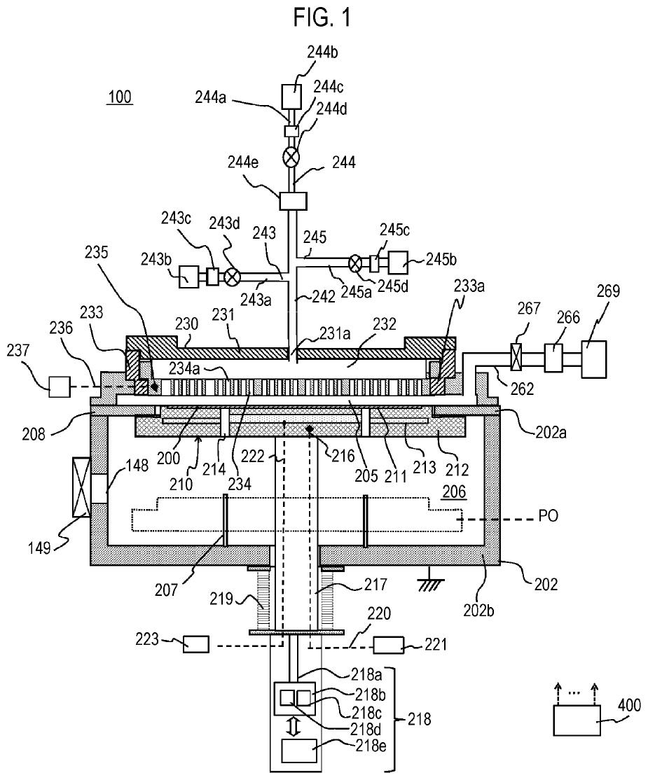

FIG. 1 is an explanatory view illustrating a substrate processing apparatus according to the present embodiment. Hereinafter, each component will be specifically described using a substrate processing apparatus 100 of FIG. 1 as an example.

The substrate processing apparatus 100 includes a vessel 202. The vessel 202 is configured as, for example, a flat sealed vessel having a circular cross section. The vessel 202 is made of a metal material such as, e.g., aluminum (Al) or stainless steel (SUS). A process space 205 for processing a substrate 200 such as a silicon wafer and a transfer space 206 through which the substrate 200 passes when the substrate 200 is transferred to the process space 205 are formed in the vessel 202. The vessel 202 is constituted by an upper vessel 202a and a lower vessel 202b. A partition plate 208 is installed between the upper vessel 202a and the lower vessel 202b.

A substrate loading/unloading port 148 adjacent to a gate valve 149 is installed on a side surface of the lower vessel 202b, and the substrate 200 moves between the lower vessel 202b and a transfer chamber (not shown) via the substrate loading/unloading port 148. A plurality of lift pins 207 are installed at the bottom of the lower vessel 202b. Furthermore, the lower vessel 202b is grounded.

A substrate support part 210 for supporting the substrate 200 is disposed in the process space 205. The substrate support part 210 includes a substrate mounting surface 211 on which the substrate 200 is held, a substrate mounting table 212 having the substrate mounting surface 211 on its surface, and a heater 213 as a heating source installed in the substrate mounting table 212. Through holes 214 through which the lift pins 207 penetrate are formed in the substrate mounting table 212 at positions corresponding to the lift pins 207, respectively.

In addition, a temperature measuring instrument 216 which is a first temperature measuring instrument for measuring the temperature of the heater 213 is included in the substrate mounting table 212. The temperature measuring instrument 216 is connected to a temperature measuring part 221 which is a first temperature measuring part via a wiring 220.

A wiring 222 for supplying electric power is connected to the heater 213. A wiring 216 is connected to a heater controller 223.

The temperature measuring part 221 and the heater controller 223 are electrically connected to a controller 400 as described hereinbelow. The controller 400 transmits control information to the heater controller 221 based on the temperature information measured by the temperature measuring part 221. The heater controller 223 controls the heater 213 by referring to the received control information.

The substrate mounting table 212 is supported by a shaft 217. The shaft 217, which penetrates the bottom of the vessel 202, is connected to an elevating part 218 outside the vessel 202.

The elevating part 218 includes a support shaft 218a for supporting the shaft 217 and an operation part 218b for lifting and rotating the support shaft 218a. The operation part 218b includes, for example, an elevating mechanism 218c including a motor for realizing the lifting, and a rotation mechanism 218d such as a gear for rotating the support shaft 218a.

An instruction part 218e as a part of the elevating part 218 for instructing the operation part 218b to perform the lifting and the rotation may be installed in the elevating part 218. The instruction part 218e is electrically connected to the controller 400. The instruction part 218e controls the operation part 218b based on an instruction from the controller 400.

The substrate mounting table 212 is configured to raise and lower the substrate 200 held on the mounting surface 211 by operating the elevating part 218 to move the shaft 217 and the substrate mounting table 212 up and down. In addition, the periphery of the lower end portion of the shaft 217 is covered with a bellows 219 such that the interior of the process space 205 is kept airtight.

The substrate mounting table 212 is lowered to a position PO where the substrate mounting surface 211 faces the substrate loading/unloading port 148 when the substrate 200 is transferred, and is raised until the substrate 200 reaches a processing position within the process space 205 as illustrated in FIG. 1, when the substrate 200 is processed. At a temperature adjusting step as described hereinbelow, the substrate mounting table 212 is moved up and down such that the distance between the heater 213 and a dispersion plate 234 as described hereinbelow becomes equal to a predetermined distance.

A shower head (also referred to as an SH) 230 as a gas dispersion mechanism is installed in an upper portion (at an upstream side) of the process space 205. A through hole 231a is formed in a lid 231 of the shower head 230. The through hole 231a communicates with a common gas supply pipe 242 as described hereinafter.

The shower head 230 has the dispersion plate 234 as a dispersion mechanism for dispersing a gas. An upstream side of the dispersion plate 234 is a buffer space 232, and a downstream side thereof is the process space 205. A plurality of through holes 234a are formed in the dispersion plate 234. The dispersion plate 234 is disposed to face the substrate mounting surface 211. The dispersion plate 234 is formed in, for example, a disc shape. The through holes 234a are formed over the entire surface of the dispersion plate 234.

A temperature measuring instrument 235 which is a second temperature measuring instrument is installed in the dispersion plate 234. The temperature measuring instrument 235 is connected to a temperature measuring part 237 which is a second temperature measuring part via a wiring 236.

The upper vessel 202a has a flange, on which a support block 233 is held and fixed. The support block 233 has a flange 233a, on which the dispersion plate 234 is held and fixed. Furthermore, the lid 231 is fixed to an upper surface of the support block 233.

The common gas supply pipe 242 is connected to the lid 231 so as to communicate with the through hole 231a formed in the lid 231 of the shower head 230.

A first gas supply pipe 243a, a second gas supply pipe 244a, and a third gas supply pipe 245a are connected to the common gas supply pipe 242. The second gas supply pipe 244a is connected to the common gas supply pipe 242.

### (First Gas Supply System)

A first gas source 243b, a mass flow controller (MFC) 243c, which is a flow rate controller (flow rate control part), and a valve 243d, which is an opening/closing valve, are installed in the first gas supply pipe 243a sequentially from the corresponding upstream side.

The first gas source 243b is a first gas (also referred to as a “first-element-containing gas”) source containing a first element. The first-element-containing gas is one of the precursor gases, i.e., processing gases. Here, the first element is, for example, silicon (Si). That is, the first-element-containing gas is, for example, a silicon-containing gas. Specifically, a hexachlorodisilane (Si₂Cl₆, also referred to as an HCD) gas is used as the silicon-containing gas.

A first gas supply system 243 (also referred to as a silicon-containing gas supply system) includes the first gas supply pipe 243a, the WC 243c, and the valve 243d.

### (Second Gas Supply System)

A second gas source 244b, a mass flow controller (WC) 244c, which is a flow rate controller (flow rate controller), and a valve 244d, which is an opening/closing valve, are installed in the second gas supply pipe 244a sequentially from the corresponding upstream side.

The second gas source 244b is a second gas (hereinafter, also referred to as a “second-element-containing gas”) source containing a second element. The second-element-containing gas is one of the processing gases. The second-element-containing gas may also be regarded as a reaction gas or a modifying gas.

Here, the second-element-containing gas contains the second element different from the first element. The second element is, for example, any one of oxygen (O), nitrogen (N), and carbon (C). In the present disclosure, it is assumed that the second-element-containing gas is, for example, a nitrogen-containing gas. Specifically, an ammonia (NH₃) gas is used as the nitrogen-containing gas.

In the case where the substrate 200 is processed with a second gas in a plasma state, a remote plasma unit 244e may be installed in the second gas supply pipe.

A second gas supply system 244 (also referred to as a reaction gas supply system) includes the second gas supply pipe 244a, the WC 244c, and the valve 244d. A plasma generating part may be included in the second gas supply system 244.

### (Third Gas Supply System)

A third gas source 245b, a mass flow controller (MFC) 245c, which is a flow rate controller (flow rate control part), and a valve 245d, which is an opening/closing valve, are installed in the third gas supply pipe 245a sequentially from the corresponding upstream side.

The third gas source 245b is an inert gas source. The inert gas is, for example, a nitrogen (N₂) gas.

A third gas supply system 245 includes the third gas supply pipe 245a, the MFC 245c, and the valve 245d.

The inert gas supplied from the inert gas source 245b acts as a purge gas for purging the gas remaining within the vessel 202 or the shower head 230 in the substrate processing process.

### (Exhaust System)

An exhaust pipe 262 communicates with the process space 205. The exhaust pipe 262 is connected to the upper vessel 202a so as to communicate with the process space 205. An auto pressure controller (APC) 266 which is a pressure controller for controlling the interior of the process space 205 to a predetermined pressure is installed in the exhaust pipe 262. The APC 266 has a valve element (not shown) whose opening degree can be adjusted, and adjusts the conductance of the exhaust pipe 262 according to an instruction from the controller 400. A valve 267 is installed at the upstream side of the APC 266 in the exhaust pipe 262. The exhaust pipe 262, the valve 267, and the APC 266 may be collectively referred to as an exhaust system.

In addition, a dry pump (DP) 269 is installed at the downstream side of the exhaust pipe 262. The DP 269 exhausts an atmosphere of the process space 205 via the exhaust pipe 262.

### (Controller)

The substrate processing apparatus 100 has the controller 400 that controls operations of the respective parts of the substrate processing apparatus 100.

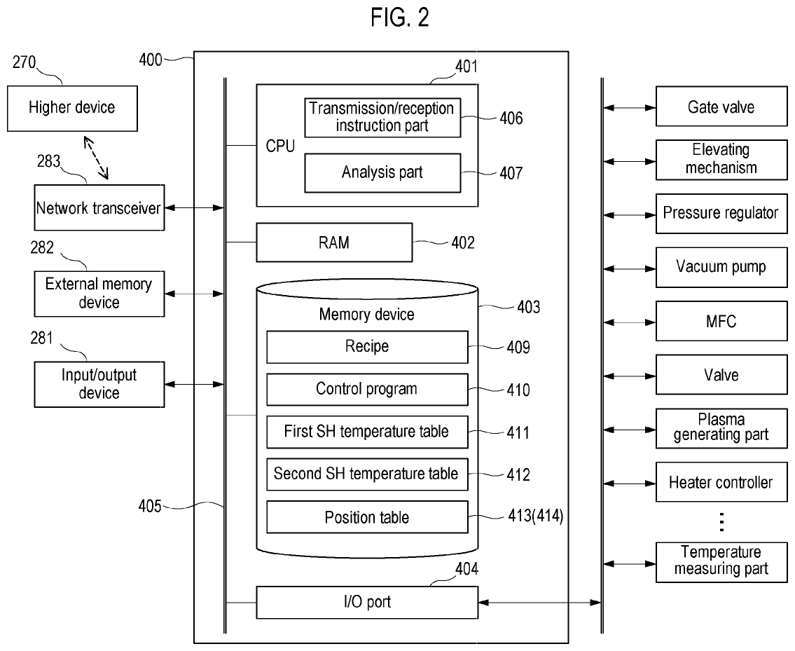

A summary of the controller 400 is illustrated in FIG. 2. The controller 400, which is a control part (control means), may be configured as a computer including a central processing unit (CPU) 401, a random access memory (RAM) 402, a storage part 403 as a memory device, and an I/O port 404. The RAM 402, the storage part 403 and the I/O port 404 are configured to exchange data with the CPU 401 via an internal bus 405. The transmission and reception of data in the substrate processing apparatus 100 are performed according to an instruction from a transmission/reception instruction part 406 which is also a function of the CPU 401.

The CPU 401 includes an analysis part 407. The analysis part 407 functions to analyze a relationship between a table stored in the storage part 403 and the temperature information measured by the first temperature measuring part and the second temperature measuring part.

A network transceiver 283 connected to a higher device 270 via a network is installed. The network transceiver 283 can receive information related to a processing history or a processing schedule, and the like of substrates 200 in a lot.

The storage part 403 includes, for example, a flash memory, a hard disk drive (HDD), or the like. A process recipe 409 for specifying sequences and conditions of substrate processing, or a control program 410 for controlling operations of a substrate processing apparatus is readably stored in the storage part 403. In addition, a first shower head temperature table 411, a second shower head temperature table 412, and a position table 413, which will be described later, are stored so as to be readable and writable.

Furthermore, the process recipe functions as a program for causing the controller 400 to execute each sequence in the substrate processing process, as described hereinbelow, to obtain a predetermined result. Hereinafter, the process recipe and the control program will be generally and simply referred to as a “program.” When the term “program” is used herein, it may indicate a case of including only the process recipe, a case of including only the control program, or a case of including both the process recipe and the control program. The RAM 402 is configured as a memory area (work area) in which a program or data read by the CPU 401 is temporarily stored.

The I/O port 404 is connected to the respective components of the substrate processing apparatus 100, such as the gate valve 149, the elevating mechanism 218, each pressure regulator, each pump, the heater controller 223, and the like.

The CPU 401 is configured to read the control program from the storage part 403 and execute the same. The CPU 401 also reads the process recipe from the storage part 403 according to an input of an operation command from an input/output device 281. In addition, the CPU 401 is configured to control, according to the contents of the process recipe thus read, the opening/closing operation of the gate valve 149, the elevating operation of the elevating mechanism 218, the operations of the temperature measuring parts 221 and 237 and the heater controller 223, the ON/OFF operation of each pump, the flow rate adjusting operation of the MFCs, the valves, and the like.

The controller 400 may be configured by installing, on the computer, the aforementioned program stored in an external memory device 282 (for example, a magnetic disk such as a hard disk, an optical disc such as a DVD, a magneto-optical disc such as an MO, or a semiconductor memory such as a USB memory). Furthermore, means for supplying the program to the computer is not limited to being supplied via the external memory device 282. For example, the program may be supplied to the computer using a communication means such as the Internet or a dedicated line, instead of using the external memory device 282. The storage part 403 or the external memory device 282 is configured as a non-transitory computer-readable recording medium. Hereinafter, the storage part 403 or the external memory device 282 will be generally and simply referred to as a “recording medium.” When the term “recording medium” is used herein, it may indicate a case of including only the storage part 403, a case of including only the external memory device 282, or a case of including both the storage part 403 and the external memory device 282.

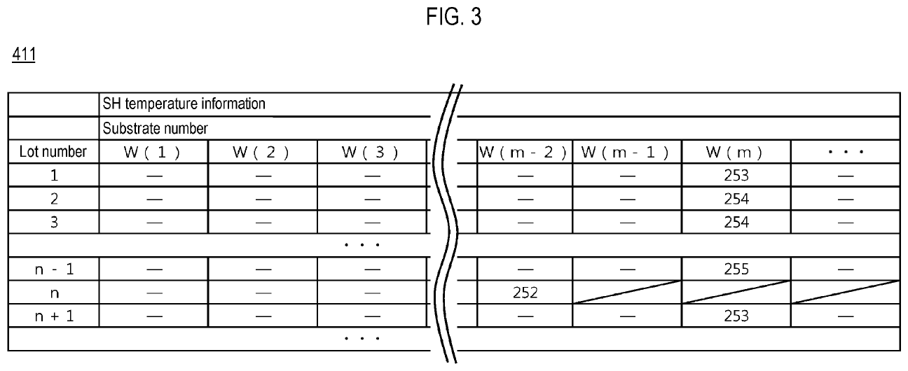

Next, the shower head temperature table 411 will be described with reference to FIG. 3. The vertical axis indicates a lot number and the horizontal axis indicates an SH temperature corresponding to a substrate number. In the table, the temperature of the shower head detected by the temperature measuring part 237 is recorded.

Here, it is assumed that the number of processed sheets per lot is m (where m is an arbitrary number). The number of lots is indicated to be larger than n+1 (where n is an arbitrary number). Meanwhile, the number of substrates may vary for each lot. For example, a first lot has an m number of substrates, but an nth lot has an (m−2) number of substrates.

In the table 411, the temperature of the shower head 230 measured at a first temperature measuring step S104 as described hereinbelow is recorded. At the first temperature measuring step S104, for example, the temperature of the shower head 230 is measured in the last substrate processing in a lot. In other words, it is measured by the substrate processing before a subsequent lot processing setting step S108 as described hereinbelow. In the case of the first lot, it is measured by mth substrate processing, and in the case of the nth lot, it is measured by (m−2)th substrate processing.

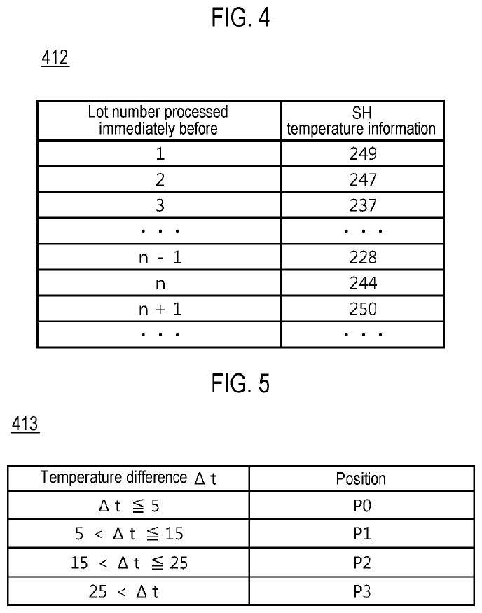

Next, the second shower head temperature table 412 will be described with reference to FIG. 4. Information on a lot number processed immediately before and SH temperature information corresponding to it are indicated. The SH temperature information is temperature information of SH measured at a second temperature measuring step S110 as described hereinbelow. In the table, the temperature of the shower head 230 detected by the temperature measuring part 237 is recorded.

Next, the position table 413 will be described with reference to FIG. 5. Here, the vertical axis is indicated by a temperature difference Δt obtained at a temperature difference calculating step S112 as described hereinbelow. The temperature difference Δt is a value obtained by subtracting the temperature measured at the second temperature measuring step S110 from the temperature measured at the first temperature measuring step S104. Here, positions P0, P1, P2, and P3 which are height positions of the substrate mounting table 212 corresponding to the Δt are further indicated. The position P0 is a wafer transfer position.

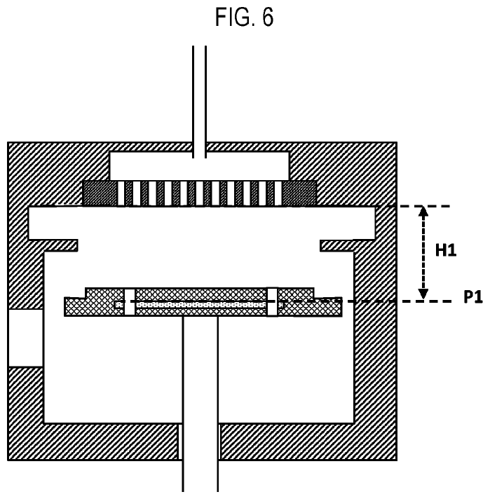

Subsequently, the positions P1, P2 and P3 will be described with reference to FIGS. 6 to 8. The positions refer to height positions of the substrate mounting table 212. More specifically, they refer to height positions of the heater 213.

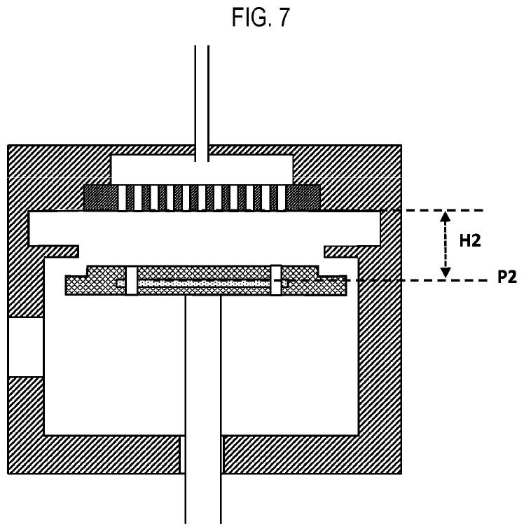

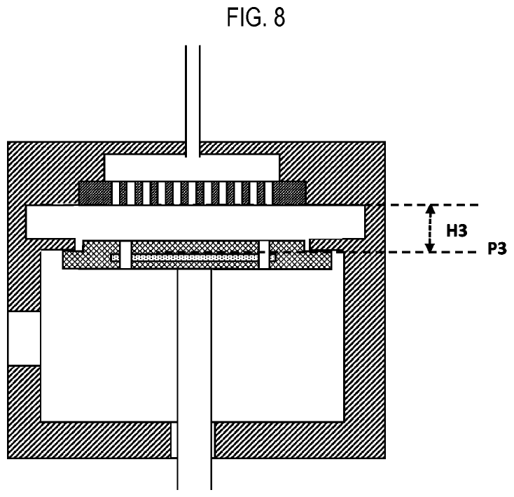

FIG. 6 illustrates the position P1, FIG. 7 illustrates the position P2, and FIG. 8 illustrates the position P3. As a relative relationship of heights, P1<P2<P3 is established. P1 is set so that the distance to the dispersion plate 234 is H1, P2 is set so that the distance to the dispersion plate 234 is H2, and P3 is set so that the distance to the dispersion plate 234 is H3. As a relative relationship of distances between the dispersion plate 234 and the substrate mounting table 212, H1>H2>H3 is established.

### (2) Substrate Processing Process

Next, a process of forming a thin film on a substrate 200 using the substrate processing apparatus 100 having the aforementioned configuration, which is one of the semiconductor manufacturing processes, will be described. In the following descriptions, the operations of the respective parts constituting the substrate processing apparatus are controlled by the controller 400.

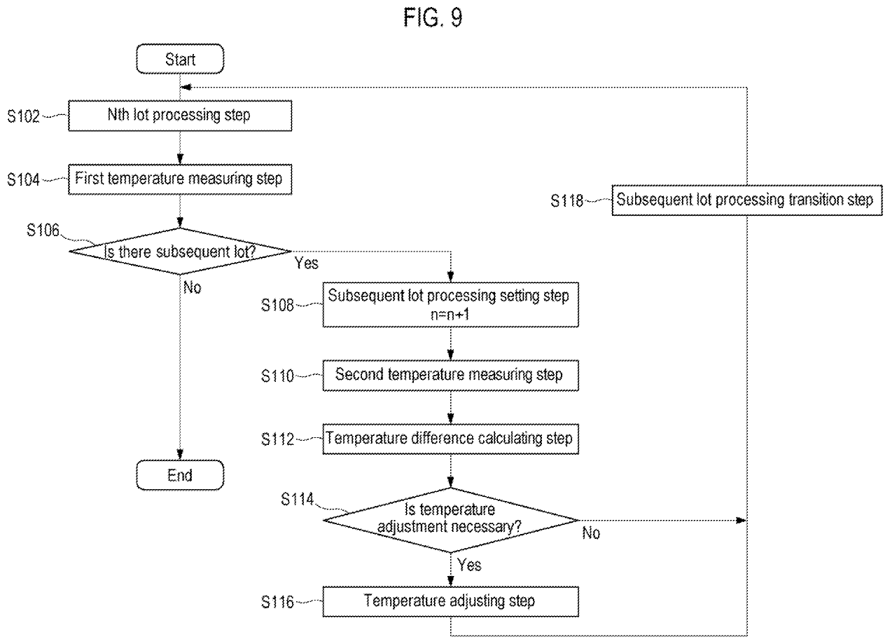

First, a substrate processing process in lot units will be described with reference to FIG. 9.

### (Nth Lot Processing Step S102)

An nth lot processing step S102 will be described.

At this step, n=1 or more.

At the nth lot processing step S102, substrates 200 of the nth lot are processed. Here, a film-forming process is performed on a predetermined number of substrates 200 of the nth lot in the process space 205. When the film formation is completed, in order to replace them with subsequent substrates 200, the processed substrates 200 are unloaded from the substrate processing apparatus 100 and then unprocessed substrates 200 are loaded thereinto. Details of the film-forming process will be described hereinbelow.

### (First Temperature Measuring Step S104)

Subsequently, the first temperature measuring step S104 will be described.

At the first temperature measuring step S104, the temperature measuring instrument 235 measures the temperature of the shower head 230 during the nth lot processing step S102. Specifically, the temperature measuring instrument 235 measures the temperature of the dispersion plate 234. The temperature measuring part 237 records the measurement value measured by the temperature measuring instrument 235 in the shower head temperature table 411 as reference data.

Next, the timing of detecting the temperature will be described.

As described above, at the nth lot processing step S102, a plurality of substrates 200 are processed. This step is performed, for example, immediately after the last substrate processing of the nth lot. In the case of the first lot, it is measured immediately after mth substrate processing, and in the case of the nth lot, it is measured immediately after (m−2)th substrate processing. By detecting at such timing, the temperature can be stably detected. This step may also be performed, for example, in parallel with the last substrate processing of the lot.

### (Determination Step S106)

Next, a determination step S106 will be described.

When the nth lot processing step S102 and the first temperature measuring step S104 are completed, the process proceeds to the determination step S106. At this step, it is determined whether a predetermined number of lots have been processed or not. If it is determined that the predetermined number of lots have been processed, the process is terminated. If it is determined that the predetermined number of lots have not been processed, the process proceeds to a subsequent lot processing setting step S108.

### (Subsequent Lot Processing Setting Step S108)

Next, the subsequent lot processing setting step S108 will be described.

At this step, the substrate processing apparatus 100 is set so as to correspond to a lot to be processed subsequently. For example, when an nth lot has been processed, it is set so that an (n+1)th lot can be processed. As an example of the setting, switching is performed so that the transfer robot can access an FOUP in which the substrates 200 of the (n+1)th lot are stored.

In addition, since this step is performed after the substrates 200 of the nth lot have been unloaded from the substrate processing apparatus 100, the substrate mounting table 212 is in a standby state at the transfer position. The subsequent lot processing setting step S108 may be simply referred to as a setting step.

### (Second Temperature Measuring Step S110)

Next, the second temperature measuring step S110 will be described.

After the subsequent lot processing setting step S108, the second temperature measuring step S110 is performed. Specifically, the temperature of the shower head 230 immediately before loading the substrates 200 of the subsequent lot is measured. At this step, the temperature measuring instrument 235 measures the temperature of the dispersion plate 234 which is a part of the shower head 230. The temperature measuring part 237 records the measurement value measured by the temperature measuring instrument 235 in the shower head temperature table 412.

As described above, at the subsequent lot processing setting step S108, the substrate mounting table 212 is in a standby state at the transfer position. Therefore, the influence of the heater 213 on the dispersion plate 230 is small. Accordingly, the temperature of the shower head 230 measured at the second temperature measuring step S110 becomes lower than the temperature during the process recorded in the table 411. The reason for a variation in the amount of decreased temperature may be considered to be, for example, a case where the time of the subsequent lot processing setting step S108 is different or there is a variation in temperature in the nth lot, which is the previous lot, or the like.

### (Temperature Difference Calculating Step S112)

Next, the temperature difference calculating step S112 will be described.

The term “temperature difference” as used herein indicates Δt illustrated in FIG. 5 and refers to a difference between the temperature measured at the first temperature measuring step S104 and the temperature measured at the second temperature measuring step S110.

For example, a difference between the temperature at the lot number n of the table 411 and the temperature at the lot number n processed just before the table 412 is calculated.

### (Determination Step S114)

Next, a determination step S114 will be described.

First, when the temperature of the shower head 230 decreases, there is a problem of reproducibility of substrate processing. For example, there is a problem that the temperature of the shower head is different between the substrate processed at the end of the nth lot processing and the substrate processed at the beginning of the (n+1)th lot.

Since the shower head 230 is disposed near the substrates 200, the temperature thereof affects the substrates 200. In particular, the dispersion plate 234 faces the surfaces of the substrates 200, and when the temperature of the dispersion plate 234 decreases, it affects the substrate processing. When the temperature of the dispersion plate 234 partially decreases, it also affects uniformization of the in-plane processing of the substrates 200.

Due to this influence, if the temperature of the shower head 230 is different, the film quality of the substrates 200 may be different. Therefore, in the present embodiment, a temperature adjusting step S116 as described hereinbelow is performed. At this step, it is determined whether the temperature adjusting step S116 is necessary.

The necessity of the temperature adjusting step S116 is determined using the table of FIG. 5. For example, when Δt is 5 degrees C. or lower as in lot number 1, it is considered that the variation in temperature does not affect the substrate processing, and it is determined that the temperature adjusting step S116 as described hereinbelow is unnecessary. If it is determined that it is not necessary, the process returns to the nth lot processing step S102 in the (n+1)th lot, in which the processing of the substrates 200 starts.

For example, when Δt is greater than 5 degrees C., it is determined that the temperature adjusting step S116 is necessary, and the process proceeds to the temperature adjusting step S116.

### (Temperature Adjusting Step S116)

Next, the temperature adjusting step S116 will be described.

As described above, when switching to the subsequent lot, since the temperature of the shower head 230 decreases, the processing situation of the substrates 200 to be processed thereafter may differ from the processing situation of the previous lot. Therefore, at this step, the temperature of the shower head 230 is adjusted to substantially the same temperature as the previous lot. A specific method will be described hereinbelow.

As described above, when Δt is higher than a predetermined temperature, the position of the substrate mounting table 212 corresponding to Δt is read out. The controller 400 moves the substrate mounting table so as to be located at the read position. In this manner, the distance between the shower head and the substrate mounting table is adjusted according to Δt, and the temperature of the shower head is adjusted to become the temperature measured at the first temperature measuring step.

Here, in a state where the heater 213 is in operation and no substrate 200 is held on the substrate mounting table 212, it approaches and heats the shower head 230 for a predetermined period of time. By making it closer to the shower head, the shower head 230 is heated to adjust the temperature so as to approach the processing situation of the previous lot.

As the temperature difference before and after the second temperature measuring step S110 is larger, namely as Δt is larger, the shower head 230 is heated by making the heater closer to the shower head 230. By doing so, even if the temperature of the shower head decreases at the time of switching to the subsequent lot, since it can be quickly returned to the heating state before maintenance, it is possible to increase the operation rate or the production efficiency of the apparatus.

### (Subsequent Lot Processing Transition Step S118)

Next, a subsequent lot process transition step S118 will be described. When the temperature adjusting step S116 is completed, or when it is determined at the determination step S114 that the temperature adjustment is unnecessary, the process goes to the subsequent lot process transition step S118.

At this step, the substrate processing apparatus 100 is controlled based on the setting at the subsequent lot processing setting step S108. For example, the substrates 100 of the subsequent lot are loaded into the substrate processing apparatus 100.

### (Film-Forming Process)

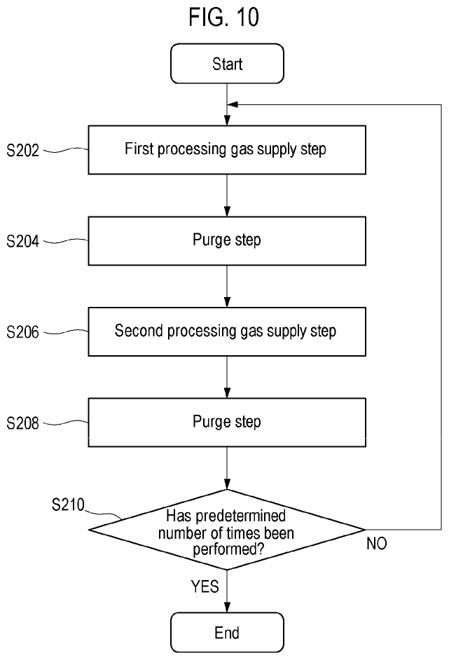

Next, a process of forming a thin film on the substrates 200 using the substrate processing apparatus 100 having the aforementioned configuration, which is one of the semiconductor manufacturing processes, will be described with reference to FIG. 10. This process is a process of performing one substrate processing during the nth lot processing step S102. That is, at the nth lot processing step S102, the film-forming process is repeated by the number of processed substrates in the lot.

Here, an example in which a silicon nitride (SiN) film is formed as a semiconductor-based thin film on the substrates 200 by alternately supplying a dichlorosilane (SiH₂Cl₂, abbreviation: DCS) gas used as the first-element-containing gas (first processing gas) and an ammonia (NH₃) gas used as the second-element-containing gas (second processing gas) will be described.

### (Substrate Loading and Mounting Process)

The substrate mounting table 212 is lowered to the transfer position of the substrates 200 to pass the lift pins 207 through the through holes 214 of the substrate mounting table 212. As a result, the lift pins 207 protrude from the surface of the substrate mounting table 212 by a predetermined height. By exhausting the atmosphere of the transfer space 206 in parallel with such operations, it is set at the same pressure as that of an adjacent vacuum transfer chamber (not shown) or at a pressure lower than that of the adjacent vacuum transfer chamber.

Subsequently, the gate valve 149 is opened to allow the transfer space 206 to communicate with the adjacent vacuum transfer chamber. Then, the substrates 200 are loaded into the transfer space 206 from the vacuum transfer chamber by using a vacuum transfer robot (not shown).

### (Substrate Processing Position Moving Process)

After a predetermined period of time has elapsed, the substrate mounting table 212 is raised to mount the substrates 200 on the substrate mounting surface 211, and is further raised to the substrate processing position as illustrated in FIG. 1.

### (Gas Supply Process)

Subsequently, the film-forming process will be described. Hereinafter, it will be described in detail with reference to FIG. 10. The film-forming process is also a cyclic process of repeating the process of alternately supplying different processing gases.

### (First Processing Gas Supply Step S202)

When the substrate mounting table 212 moves to the substrate processing position, the atmosphere is exhausted from the process chamber 201 via the exhaust pipe 262 to adjust the internal pressure of the process chamber 201.

When the temperature of the substrates 200 reaches a predetermined temperature, for example, 500 to 600 degrees C., while adjusting to a predetermined pressure, a processing gas, for example, a DCS gas, is supplied from the common gas supply pipe 242 to the process chamber. The supplied DCS gas forms a silicon-containing layer on the substrates 200.

### (Purge Step S204)

After the supply of the DCS gas is stopped, the process space 201 is purged by supplying an N₂ gas from the third gas supply pipe 245a. Thus, the DCS gas, which is not bonded to the substrates 200 at the first processing gas supply step S202, is removed from the process space 201 via the exhaust pipe 262.

At the purge step S204, a large amount of purge gas is supplied in order to remove the residual DCS gas in the substrates 200, the process space 201, and the buffer space 232 to increase the exhaust efficiency.

### (Second Processing Gas Supply Step S206)

After the purging of the buffer space 232 and the process space 201 is completed, a second processing gas supply step S206 is subsequently performed. At the second processing gas supply step S206, the valve 244d is opened and an NH₃ gas which is the second-element-containing gas as the second processing gas starts to be supplied into the process space 201 via the remote plasma unit 244e and the shower head 230. At this time, the WC 244c is adjusted such that the flow rate of the NH₃ gas becomes a predetermined flow rate. The supply flow rate of the NH₃ gas is, for example, 1,000 to 10,000 sccm. Also, at the second processing gas supply step S206, the valve 245d of the third gas supply system is opened to supply an N₂ gas from the third gas supply pipe 245a. By doing so, it is possible to prevent the NH₃ gas from entering the third gas supply system.

The NH₃ gas which becomes a plasma state in the remote plasma unit 244e is supplied into the process space 201 via the shower head 230. The supplied NH₃ gas reacts with a silicon-containing layer on the substrates 200. Then, the silicon-containing layer as already formed is modified by plasma of the NH₃ gas. Thus, for example, a silicon nitride layer (SiN layer) which is a layer containing a silicon element and a nitrogen element is formed on the substrates 200.

After the lapse of a predetermined period of time from the start of the supply of the NH₃ gas, the valve 244d is closed to stop the supply of the NH₃ gas. The supply time period of the NH₃ gas is, for example, 2 to 20 seconds.

### (Purge Step S208)

After the supply of the NH₃ gas is stopped, a purge step S208 similar to the purge step S204 described above is performed. Since the operation of each part at the purge step S208 is similar to that at the purge step S204 described above, a description thereof will be omitted here.

### (Determination Step S210)

The first processing gas supply step S202, the purge step S204, the second processing gas supply step S206, and the purge step S208 described above are set to one cycle, and the controller 400 determines whether or not the cycle has been performed a predetermined number of times (n cycles). When the cycle has been performed a predetermined number of times, an SiN layer having a desired film thickness is formed on the substrates 200.

### (Substrate Unloading Process)

When the SiN layer having a desired film thickness is formed, the substrate mounting table 212 is lowered to move the substrates 200 to the transfer position. After moving to the transfer position, the substrates 200 are unloaded from the transfer space 206.

### Second Embodiment of the Present Disclosure

Next, a second embodiment of the present disclosure will be described.

In the second embodiment, the contents related to the table 411 are different. Other components are similar to those of the first embodiment. Hereinafter, differences from the first embodiment will be mainly described.

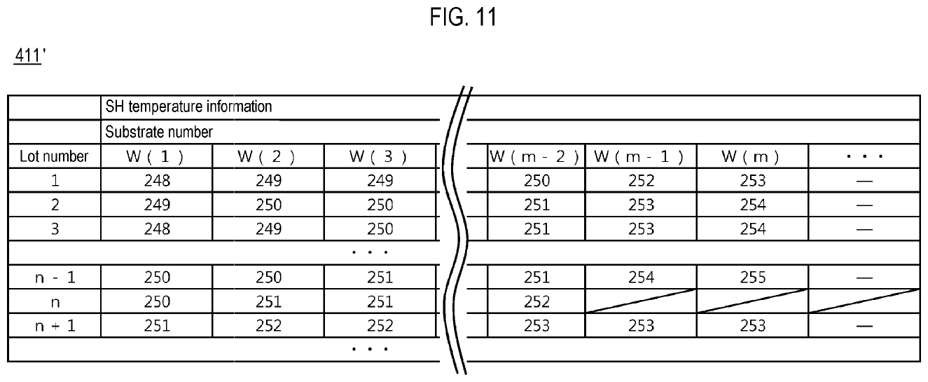

A table 411′ of the second embodiment is illustrated in FIG. 11. The table 411′ and the table 411 are different in that, the temperature of the shower head at the time of processing the last substrates in the lot is recorded in the table 411 of the first embodiment, whereas the temperature data of the shower head 230 measured every time the substrates in the lot are processed is recorded in the table 411′.

Subsequently, the reason for measuring the temperature for each substrate 200 in the table 411′ will be described. When a plurality of substrates 200 are continuously processed by a single wafer processing apparatus, heat is accumulated in the dispersion plate 234. In that case, the temperature of the dispersion plate 234 increases according to the number of processed substrates 200.

However, as the number of processed substrate 200 increases, the byproduct adhered to the dispersion plate 234 increases. The adhered byproduct may often reduce the influence of heat from the heater 213. On the other hand, it is difficult to control the adhesion amount or the adhesion position of the byproduct.

Therefore, although the temperature of the dispersion plate 234 increases according to the number of processed substrates, the increased amount varies depending on the lots.

Accordingly, in the present embodiment, optimum reference data is calculated from data obtained by accumulating the number of processed substrates 200 and the temperature of the shower head 230 at that time in the table 411′.

Since the optimum reference data is calculated from the previous accumulated data, it is possible to set an optimum position even if a measurement error or the like occurs.

### Third Embodiment of the Present Disclosure

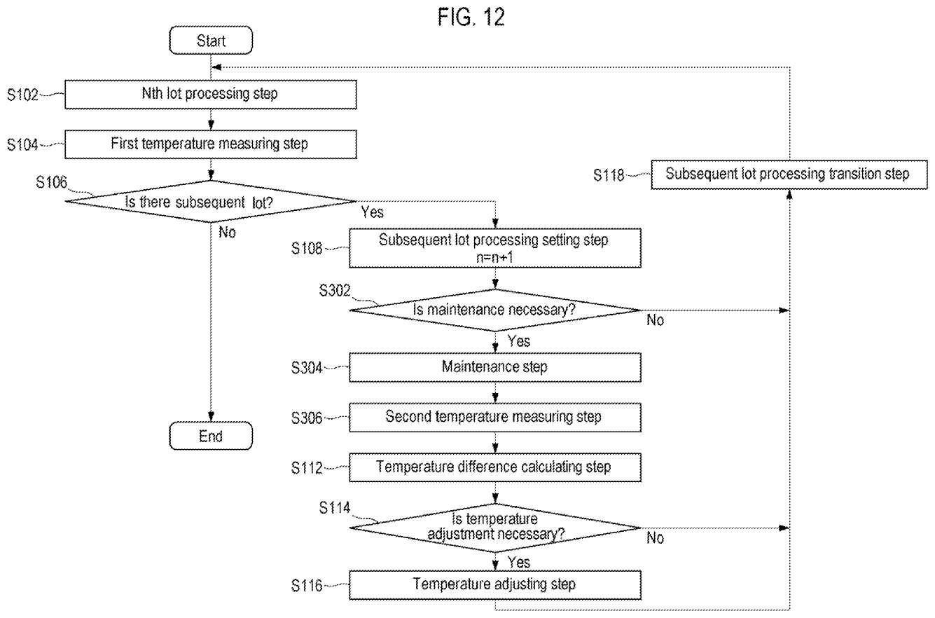

Next, a third embodiment of the present disclosure will be described with reference to FIG. 12.

The third embodiment is based on the assumption that the substrate processing apparatus will be maintained, and a part of the substrate processing process is different from that of the first embodiment. Hereinafter, (4) substrate processing process which is the difference will be mainly described.

### (4) Substrate Processing Process

A process of forming a thin film on a substrate 200 using the substrate processing apparatus 100 having the aforementioned configuration, which is one of the semiconductor manufacturing processes, will be described. In the following descriptions, the operations of the respective parts constituting the substrate processing apparatus are controlled by the controller 400.

First, the substrate processing process in lot units will be described with reference to FIG. 12. The nth lot processing step S102 to the determination step S108 and the temperature calculating step S112 to the temperature adjusting step S116 are similar to those of the first embodiment, and therefore, a detailed description thereof will be omitted.

### (Determination Step S302)

A determination step S302 will be described. At this step, it is determined whether or not the substrate processing apparatus 100 needs to be maintained. In the maintenance, for example, deposit including the byproduct adhered to the wall of the process chamber forming the process space 205 or the dispersion plate 234, or the like is removed. By removing the deposit, it is not affected by the byproduct when processing the substrates.

Accordingly, at this determination step, if it is not affected by the byproduct, it is determined as “No”, and if it is affected by the byproduct, it is determined as “Yes”. As a quantitative criterion concerning the influence of the byproduct, determination is made based on, for example, the number of processed substrates, the operation time of the apparatus, the supply time period of a gas, or the like.

If it is determined as “Yes” at the determination step S302, the process proceeds to the maintenance step S304. If it is determined as “No” at the determination step S302, the process proceeds to the subsequent lot process.

### (Maintenance Step S304)

If it is determined as “Yes” at the determination step S302, the process proceeds to the maintenance step S304. At the maintenance step S304, the deposit is removed by, for example, dry etching or the like.

However, after the maintenance step S304, the temperature of the shower head 230 decreases. This is for stopping the operation of the heater 213 or for removing the deposit using liquid or gas, or the like of a low temperature.

When the temperature of the shower head 230 decreases at the maintenance step S304, as in the first embodiment, there is a problem that the processing situation differs between the previous lot process and the subsequent lot process.

Therefore, in the present embodiment, the temperature adjusting step S114 is performed later.

### (Second Temperature Measuring Step S306)

When the maintenance step S304 is completed, the process proceeds to a second temperature measuring step S306.

At the second temperature measuring step S306, after the maintenance step S304, the temperature measuring instrument 235 measures the temperature of the shower head 230. Specifically, it measures the temperature of the dispersion plate 234. The temperature measuring part 237 records the measurement value measured by the temperature measuring instrument 235 in the shower head temperature table 412.

Based on a second temperature measured as described above, as in the first embodiment, a temperature difference is calculated at the temperature difference calculating step S112, the position of the substrate mounting table is set and the temperature of the shower head 230 is adjusted at the temperature adjusting step S116.

When the temperature adjusting step S116 is completed, the process goes to the subsequent lot processing setting step S208 to prepare a lot to be processed subsequently.

As described above, according to the present embodiment, since the temperature can be adjusted even if there was a maintenance step, it is possible to perform the process without variations.

### Fourth Embodiment of the Present Disclosure

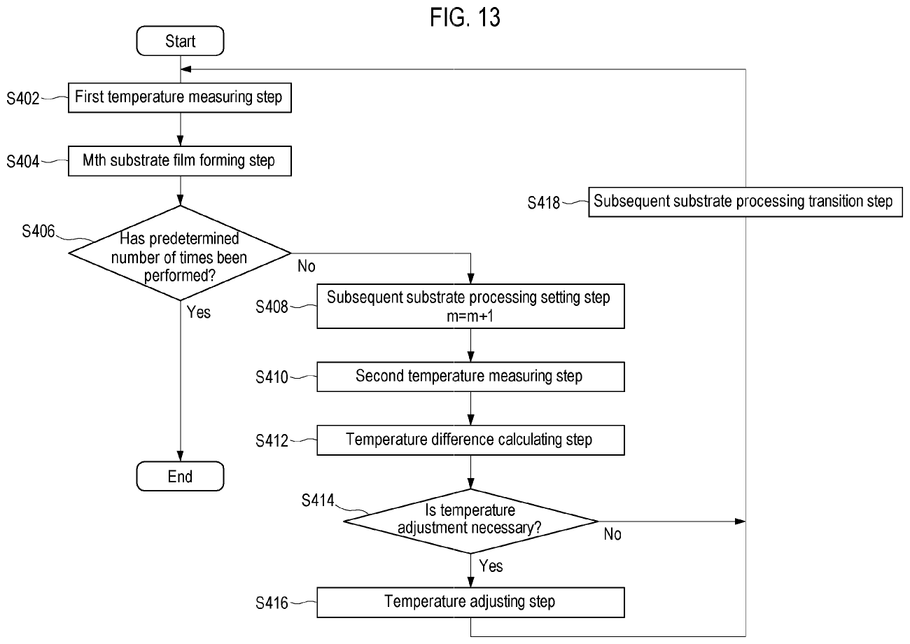

Next, a fourth embodiment of the present disclosure will be described with reference to FIGS. 13 to 15.

The fourth embodiment is different from the first embodiment in the timing of measuring the temperature of the shower head 230. Specifically, in the first embodiment, the temperature was measured for each lot, but in the present embodiment, the temperature is measured every time the substrates in the lot are processed. The differences will be mainly described hereinbelow.

### (First Temperature Measuring Step S402)

A first temperature measuring step S402 will be described.

At the first temperature measuring step S402, the temperature measuring instrument 235 measures the temperature of the shower head 230. Specifically, it measures the temperature of the dispersion plate 234. The temperature measuring part 237 records the measurement value measured by the temperature measuring instrument 235 in the shower head temperature table 411 as reference data.

### (Mth Substrate Film-Forming Step S404)

An mth substrate film-forming step S404 will be described.

Here, m=1 or more.

At the mth substrate film-forming step S404, an mth substrate 200 in a lot is processed. The process is similar to the film-forming process described above. Here, a film-forming process is performed on the substrate 200 in the process space 205. When the film-forming process is completed, in order to replace it with a subsequent substrate 200, the processed substrate 200 is unloaded from the substrate processing apparatus 100.

### (Determination Step S406)

Next, a determination step S406 will be described.

When the mth substrate film-forming step S404 is completed, the process goes to the determination step S406. At this step, it is determined whether a predetermined number of substrates 200 have been processed or not. If it is determined that the predetermined number of substrates have been processed, the process is terminated. If it is determined that the predetermined number of sheets have not been processed, the process goes to a subsequent substrate processing setting step S408.

### (Subsequent Substrate Processing Setting Step S408)

Next, the subsequent substrate processing setting step S408 will be described.

Here, it is set to load substrates 200 to be processed subsequently. For example, when processing the mth substrate 200, it is set to load an (m+1)th substrate 200.

In addition, since this step is performed after the mth substrate 200 has been unloaded from the substrate processing apparatus 100, the substrate mounting table 212 is in a standby state at the transfer position. The subsequent substrate processing setting step S408 may be simply referred to as a setting step.

### (Second Temperature Measuring Step S410)

Next, a second temperature measuring step S410 will be described.

The second temperature measuring step S410 is performed in parallel with the subsequent substrate processing setting step S408. More specifically, the temperature immediately before the subsequent substrate 200 is loaded is measured. Here, the temperature measuring instrument 235 measures the temperature of the shower head 230. Specifically, it measures the temperature of the dispersion plate 234. The temperature measuring part 237 records the measurement value measured by the temperature measuring instrument 235 in the shower head temperature table 412.

The temperature of the shower head at this time may be higher or lower than the temperature during the process as follows.

If the temperature of the shower head is lower, it is for the following reason. At the subsequent substrate processing setting step S408, the substrate mounting table 212 is in a standby state at the transfer position. Therefore, the influence of the heater 213 on the dispersion plate 230 is small. Accordingly, the temperature of the shower head 230 measured at the second temperature measuring step S210 may be lower than the temperature during the process recorded in the table 411.

On the other hand, if the temperature of the shower head is higher than the temperature recorded during the process, it is for the following reason. When a cumulative number of processed substrates increases, heat is accumulated in the shower head 230. Therefore, the temperature of the shower head may be higher than the temperature during the process recorded in the table 411.

### (Temperature Difference Calculating Step S412)

Next, a temperature difference calculating step S412 will be described.

The term “temperature difference” as used herein refers to Δt illustrated in FIG. 14, which is a value calculated by subtracting the temperature measured at the second temperature measuring step S410 from the temperature measured at the first temperature measuring step S302.

### (Determination Step S414)

Next, a determination step S414 will be described.

At the determination step S414, it is determined whether a temperature adjusting step S416 is necessary or not.

The necessity of the temperature adjusting step S416 is determined using the table 414 of FIG. 14. For example, when −5 degrees C<Δt≤5 degrees C., it is considered that the variation in temperature does not affect the substrate processing, and it is determined that the temperature adjusting step S416 as described hereinbelow is unnecessary. If it is determined that it is not necessary, the (m+1)th substrate processing is performed.

For example, if the temperature difference is greater than 5 degrees C. or less than −5 degrees C., it is determined that the temperature adjusting step S416 is necessary, and the process proceeds to temperature adjusting step S416.

### (Temperature Adjusting Step S416)

Next, the temperature adjusting step S416 will be described.

As described above, since the temperature of the shower head 230 changes after substrate replacement, the processing situation of the substrates 200 processed thereafter may differ from the mth substrate film-forming step. Therefore, at this step, the temperature of the shower head 230 is adjusted to a temperature substantially equal to that of the mth substrate film-forming step. A specific method will be described hereinbelow.

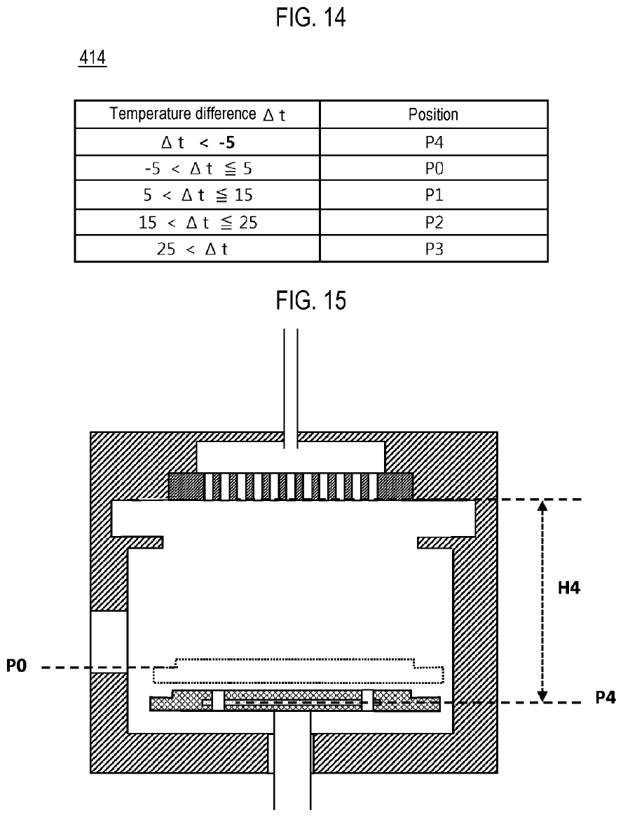

As described above, if Δt is higher than a predetermined temperature or Δt is lower than the predetermined temperature, the position of the substrate mounting table 212 corresponding to Δt is read out. When Δt is less than −5 degrees C., namely lower than the predetermined temperature, the substrate mounting table 212 is allowed to wait at a position P4 illustrated in FIG. 15 so as not to be further heated. The position P4 is set to a position lower than the position P0 to have a distance H4 which does not affect the shower head 230 by the heater 213.

Furthermore, if Δt is 5 degrees C. or more, the position is set such that the substrate mounting table 212 approaches the shower head 230 according to Δt.

The controller 400 moves the substrate mounting table so as to be at the read position.

By doing so, even if the temperature of the shower head is lowered or raised at the time of substrate replacement, since the temperature of the shower head is quickly returned to the heating state before maintenance, it is possible to increase the operation rate or the production efficiency of the apparatus.

### (Subsequent Substrate Processing Transition Step S418)

Next, a subsequent substrate processing transition step S418 will be described. When the temperature adjusting step S416 is completed, or when it is determined at step S314 that temperature adjustment is unnecessary, the process proceeds to the subsequent substrate processing transition step S418.

Here, the substrate processing apparatus 100 is controlled based on the setting at the subsequent substrate processing setting step S408. For example, the substrates 100 to be processed subsequently are loaded into the substrate processing apparatus 100.

Next, the reason why the first substrate temperature measuring step S402 is performed before the mth substrate film-forming step S404 will be described.

When the substrates 100 are continuously processed, since heat is accumulated in the shower head 230 every time they are processed, the temperature gradually rises. Therefore, even if the substrates 100 are exchanged for the substrates 100 to be processed subsequently, there is a problem that the heat hardly decreases.

Under such circumstances, when measuring the temperature during substrate processing, a temperature significantly higher than a desired temperature may be detected. Even if Δt is calculated on the basis of such a temperature, there is a possibility that the temperature adjustment is performed in a state higher than the desired temperature and thus an appropriate film-forming process is not performed.

Therefore, in the present embodiment, the first temperature measuring step is performed before the mth substrate film-forming step. By doing so, the temperature of the shower head 230 can be always detected within a desired temperature range. Therefore, the temperature can be stably adjusted.

### Other Embodiments

While the embodiments of the present disclosure have been specifically described above, the present disclosure is not limited to the aforementioned embodiments but may be differently modified without departing from the spirit of the present disclosure.

For example, in each of the aforementioned embodiments, there has been described as an example a case where an SiN film is formed on the substrates 200 by alternately supplying a DCS gas used as the first-element-containing gas (first processing gas) and an NH₃ gas used as the second-element-containing gas (second processing gas) in the film-forming process performed by the substrate processing apparatus, but the present disclosure is not limited thereto. That is, the processing gas used for the film-forming process is not limited to the DCS gas, the NH₃ gas, or the like, and other kinds of thin films may be formed using other kinds of gas. Furthermore, even when three or more kinds of processing gases are used, the present disclosure may be applied as long as the film-forming process is performed by alternately supplying those gases. Specifically, the first element is not Si, but may be various elements such as, e.g., Ti, Zr, Hf, and the like rather than Si. Furthermore, the second element may be, for example, Ar or the like rather than N.

In addition, for example, in each of the aforementioned embodiments, the film-forming process is exemplified as the process performed by the substrate processing apparatus, but the present disclosure is not limited thereto. That is, in addition to the film-forming process exemplified in each of the embodiments, the present disclosure may also be applied to a process of forming a film other than the thin film exemplified in each of the embodiments. Furthermore, the specific contents of the substrate processing are not an issue, and the present disclosure may be applied to a case of performing not only th3e film-forming process but also other substrate processing such as annealing treatment, diffusion treatment, oxidation treatment, nitriding treatment, lithography treatment and the like. Moreover, the present disclosure may also be applied to other substrate processing apparatuses such as, e.g., an annealing processing apparatus, an etching apparatus, an oxidation processing apparatus, a nitriding processing apparatus, an exposure apparatus, a coating apparatus, a drying apparatus, a heating apparatus, a processing apparatus using plasma and the like. In the present disclosure, these apparatuses may also be combined. In addition, some of the components of one embodiment may be replaced by the components of another embodiment, and the components of another embodiment may be added to the components of one embodiment. Also, the addition, deletion and replacement of other components may be made for some of the components of each embodiment.

According to the present technique, it is possible to make a film quality between the substrates uniform even if a processing environment between the substrates changes in a substrate processing apparatus that heat-treats substrates.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A method of manufacturing a semiconductor device in a substrate processing apparatus, comprising:
forming a film by heating a substrate held on a substrate mounting table by a heater installed in the substrate mounting table and supplying a gas from a shower head installed at a position facing the substrate mounting table to the substrate;
performing a first temperature measurement by measuring a first temperature of the shower head and storing a measurement value of the first temperature as reference data in a storage part;
unloading the substrate from the substrate processing apparatus;
performing a second temperature measurement by measuring a second temperature of the shower head after unloading the substrate and before loading a subsequent substrate, the first temperature being higher than the second temperature;
calculating a difference between the first temperature and the second temperature;
determining an adjusted position of the substrate mounting table based on the difference between the first temperature and the second temperature;
adjusting a distance between the shower head and the substrate mounting table by moving the substrate mounting table to the adjusted position, in a state where the subsequent substrate is not held on the substrate mounting table and the heater is in operation;
loading the subsequent substrate on the substrate mounting table in the substrate processing apparatus; and
forming a subsequent film by heating the subsequent substrate held on the substrate mounting table by the heater and supplying the gas from the shower head.

2. The method of claim 1, wherein, in the act of determining the adjusted position of the substrate mounting table, the adjusted position of the substrate mounting table is determined to be closer to the shower head as the difference between the first temperature and the second temperature increases.

3. The method of claim 2, wherein the substrate processed in the act of forming the film is one of substrates of an nth lot and the subsequent substrate is one of substrates of an (n+1)th lot.

4. The method of claim 3, wherein the reference data is calculated according to temperature data recorded when each of the substrates processed in the nth lot is processed and information on the number of the substrates processed in the nth lot.

5. The method of claim 4, wherein a maintenance process is performed between the substrate processed in the act of forming the film and the subsequent substrate.

6. The method of claim 3, wherein a maintenance process is performed between the substrate processed in the act of forming the film and the subsequent substrate.

7. The method of claim 2, wherein the reference data is calculated according to temperature data recorded when each of the substrates processed in the nth lot is processed and information on the number of substrates processed in the nth lot.

8. The method of claim 7, wherein a maintenance process is performed between the substrate processed in the act of forming the film and the subsequent substrate.

9. The method of claim 2, wherein a maintenance process is performed between the substrate processed in the act of forming the film and the subsequent substrate.

10. The method of claim 1, wherein the substrate processed in the act of forming the film is one of substrates of an nth lot and the subsequent substrate is one of substrates of an (n+1)th lot.

11. The method of claim 10, wherein the reference data is calculated according to temperature data recorded when each of the substrates processed in the nth lot is processed and information on the number of the substrates processed in the nth lot.

12. The method of claim 11, wherein a maintenance process is performed between the substrate processed in the act of forming the film and the subsequent substrate.

13. The method of claim 10, wherein a maintenance process is performed between the substrate processed in the act of forming the film and the subsequent substrate.

14. The method of claim 1, wherein the reference data is calculated according to temperature data recorded when each of the substrates processed in the nth lot is processed and information on the number of substrates processed in the nth lot.

15. The method of claim 14, wherein a maintenance process is performed between the substrate processed in the act of forming the film and the subsequent substrate.

16. The method of claim 1, wherein a maintenance process is performed between the substrate processed in the act of forming the film and the subsequent substrate.
